(19) United States
(12) Patent Application Publication
(10) Pub. No.: US 2015/0102818 A1
(43) Pub. Date: Apr. 16, 2015

(54) METHOD AND DEVICE FOR DETERMINING A BATTERY STATUS OF A VEHICLE BATTERY IN A VEHICLE

(71) Applicant: Robert Bosch GmbH, Stuttgart (DE)

(72) Inventors: Michael Rueger, Muenchen (DE); Andre Boehm, Kornwestheim (DE)

(21) Appl. No.: 14/512,685

(22) Filed: Oct. 13, 2014

(30) Foreign Application Priority Data
Oct. 14, 2013 (DE) 10 2013 220 691.7

(51) Int. Cl. G01R 31/36

(52) U.S. Cl. CPC G01R 31/3634; G01R 31/3679
USPC 324/427

(57) ABSTRACT

A method and a device for determining a battery status of a vehicle battery in a vehicle. In this context, complete discharging (S1) of the vehicle battery by vehicle-internal loads of the vehicle, complete charging (S2) of the vehicle battery, measuring (S3) a capacity and/or an energy content of the vehicle battery during the charging of the vehicle battery, and determining (S4) the battery status by means of the capacity and/or the energy content of the vehicle battery take place. The inventive method and the inventive device are advantageous since no additional hardware, apart from the hardware which is otherwise also necessary in the user mode, and also no specialist personnel are necessary to obtain a regular determination of the battery status of a vehicle battery.

### BACKGROUND OF THE INVENTION

The present invention relates to a method and to a device for determining a battery status of a vehicle battery in a vehicle.

Vehicle batteries for automobile applications are subject to aging which changes the chemical and electrical properties of the vehicle battery. As a result of aging, the capacity of vehicle batteries decreases continuously. At the same time, the internal resistance increases. The energy content is therefore reduced more than the capacity in percentage terms.

This has effects on various algorithms which are executed by a responsible battery management system, and on further systems whose calculations are based on the battery status (for example a range calculation).

### SUMMARY OF THE INVENTION

The method according to the invention for determining a battery status of a vehicle battery in a vehicle comprises complete discharging of the vehicle battery by vehicle-internal loads of the vehicle, complete charging of the vehicle battery, measuring a capacity and/or an energy content of the vehicle battery during the charging of the vehicle battery, and determining the battery status by means of the capacity and/or the energy content of the vehicle battery.

The device according to the invention for determining a battery status of a vehicle battery in a vehicle comprises a discharge unit which is configured to discharge completely a vehicle battery by means of vehicle-internal loads of the vehicle, a charging unit which is configured to charge the vehicle battery completely, a measuring unit which is configured to measure a capacity and/or an energy content of the vehicle battery during the charging of the vehicle battery, and a determining unit which is configured to determine the battery status by means of the capacity and/or the energy content of the vehicle battery.

The inventive method and the inventive device are advantageous since no additional hardware, apart from the hardware which is otherwise also necessary in the user mode, and also no specialist personnel are necessary to obtain a regular determination of the battery status of a vehicle battery. In this way, the battery status can be determined automatically or by a vehicle user. Service costs are therefore reduced. In addition, more frequent determination of the battery status is therefore made possible, as a result of which an up-to-date and therefore precise battery status can be made available for use by further vehicle systems.

It is advantageous if in an introductory method step a first decision parameter is interrogated, and a decision as to whether the method is carried on is carried out on the basis of a comparison of the first decision parameter with a given threshold value, wherein the first decision parameter is, in particular, a parameter which describes a period of time, a mileage or kilometerage of the vehicle, a charge throughput rate of the vehicle battery and/or an energy throughput rate of the vehicle battery. In this way, the method is executed when it is probable that a battery status which is determined at a relatively early point in time no longer corresponds to the actual battery status. Continuous, time-consuming measurements are therefore avoided.

The charging of the vehicle battery is preferably carried out with an average discharging current or an average discharging power of the vehicle battery. Since the impedance of the battery is approximately identical in the charging direction and discharging direction, particularly precise energy measurement is therefore made possible. In addition, the battery status which is determined in this way therefore also corresponds to a status which the battery has during regular operation.

Likewise, the discharging of the vehicle battery is carried out during use of the vehicle in the driving mode, wherein an energy requirement which is not covered by the vehicle battery is covered by an internal combustion engine. The vehicle can therefore continue to be used during the discharging.

In particular, the charging of the vehicle battery is carried out during use of the vehicle in the driving mode, wherein a charge current is made available by a generator which is driven a using an internal combustion engine. The vehicle can therefore continue to be used during the charging.

Furthermore, it is advantageous if before completely discharging the vehicle battery an interrogation of a second decision parameter takes place, wherein inputting of the second decision parameter by a user is preferably made possible, and the method is ended or carried on as a function of the second decision parameter. It is therefore ensured that a user has the possibility of aborting the execution of the method before the discharging of the vehicle battery. This prevents the vehicle being in a non-operationally-ready state if a use is desired by the user.

In particular, a weighting takes place in which a resulting battery status is determined by means of a weighted interpolation of the determined battery status with a battery status which has been determined at an earlier point in time. Such an interpolation compensates possible measurement errors and inaccuracies if the latter occur only in the course of a single determination of the battery status. However, repeatedly occurring characteristics appear increasingly in the result of the determination.

In addition it is advantageous if the discharging of the vehicle battery comprises a concluding phase in which the battery voltage is regulated to a constant voltage value. Complete discharging of the vehicle battery is therefore ensured.

Furthermore, it is advantageous if the charging of the vehicle battery is carried out by means of an electric motor of the vehicle which is in a generator mode. Such an electric motor could be driven, for example, via an additional internal combustion engine. In this way, a typical charging current is obtained, as a result of which in turn the precision of the determined battery status increases. In addition, use of the vehicle during the charging phase is made possible.

### BRIEF DESCRIPTION OF THE DRAWINGS

Exemplary embodiments of the invention are described below in detail with reference to the accompanying drawing, in which:

FIG. 1 shows a flowchart of the method according to the invention in a first embodiment, and

FIG. 2 shows a flowchart of the method according to the invention in a second embodiment.

### DETAILED DESCRIPTION

The inventive method and the inventive device permit a battery status of a vehicle battery in a vehicle to be measured and/or determined. The method according to the invention is suitable, in particular, for measuring a capacity in a hybrid-electric vehicle (HEV) or a plug-in-hybrid-electric vehicle (PHEV). It is independent of changes of a battery behavior due to aging. Aging of the vehicle battery can lead, for example, to a change in an open-circuit voltage profile or impedance of the vehicle battery.

In the method, unknown influences on the battery status owing to changes in an open-circuit voltage or impedance of the vehicle battery are ruled out by complete measurement (between 0% of the state of charge and 100% of the state of charge) in the vehicle. In this context, only the hardware which is available in any case in the vehicle is used.

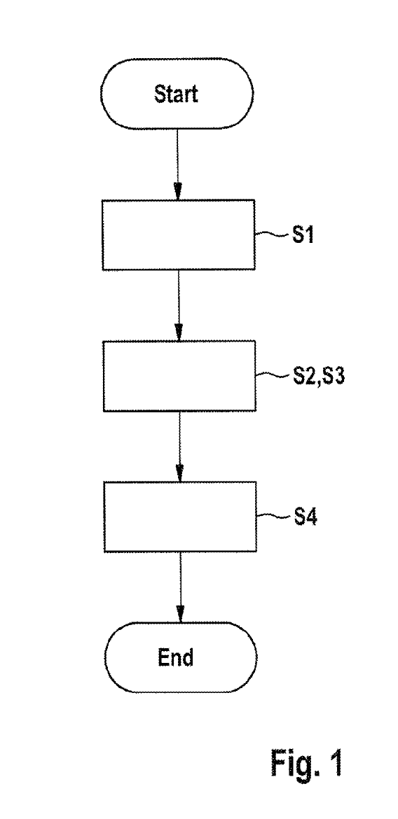

FIG. 1 shows a flowchart of the method according to the invention in a first embodiment. The method can be started, for example, by a start signal of an independent vehicle system or by a request by a user.

In a first method step S1, complete discharging of the vehicle battery is carried out by vehicle-internal loads of the vehicle. The term vehicle-internal loads is used to refer here to components of the vehicle which are also available in a user mode of the vehicle. Examples of such components are a heater (if appropriate compensated by simultaneous operation of the cooling system), pumps, inverter/E-machines or similar components of the vehicle. In this context, in particular a use of high-voltage loads is advantageous. According to the invention, no additional service equipment is necessary to discharge the vehicle battery.

The first method step S1 of the discharging of the vehicle battery can comprise a concluding phase in which a battery voltage of the vehicle battery is regulated to a constant voltage value. This could take place, for example, by means of corresponding connection of vehicle-internal loads to a current consumer/load which can be regulated (for example a lamp with brightness which can be regulated). Complete discharging of the vehicle battery is therefore ensured.

In a second method step S2, complete charging of the vehicle battery is carried out. The charging can be carried out using a connected external or internal charging device. Likewise, charging is possible by means of a vehicle-internal generator which is driven, for example, using an internal combustion engine or some other energy source. The charging is preferably carried out with a charging current which is as constant as possible.

It is advantageous here if the charging of the vehicle battery is carried out in the second method step S2 with an average discharging current or an average discharging power of the vehicle battery. This means that an amplitude of the charging current corresponds to an average amplitude of a discharging current or that a charging power corresponds to an average discharging power. The average discharging current or the average discharging power could be determined here, for example, from an average discharging time between two states of charge of the vehicle battery in a user mode or by forming mean values of a plurality of discharging currents detected in the user mode or a plurality of discharging powers detected in the user mode. The assumption of approximately identical impedance of the vehicle battery in the charging direction and discharging direction therefore permits particularly precise energy measurement. The average discharging current or the average discharging power can also be determined by means of a predefined value.

In this context, the second method step S2 of charging the vehicle battery can comprise a concluding phase in which a charging voltage which is applied to the contacts of the vehicle battery is regulated to a constant voltage value. This could be carried out, for example, by corresponding regulation of the charging device. Complete charging of the vehicle battery is therefore ensured.

During the charging of the vehicle battery in the second method step S2, a capacity is measured (in ampere hours) and/or an energy content (in watt hours) of the vehicle battery within the scope of a third method step S3 which is executed simultaneously. The capacity could be measured here, for example, using a charging current which is determined over the duration of the charging of the vehicle battery. The energy content could be measured here, for example, using a charging current and a charging voltage which are determined over the duration of the charging of the vehicle battery.

In a fourth method step S4, a battery status is determined by means of the capacity and/or the energy content of the vehicle battery. Such a battery status is also referred to as “State of Health” (SOH) of the vehicle battery. On the basis of such a battery status, various calculations can be carried out by means of further systems located in the vehicle. In this way, for example a range estimation could be carried out on the basis of this battery status. The information can additionally be used for diagnostic purposes.

The fourth method step S4 can comprise a weighting in which a resulting battery status is determined by means of a weighted interpolation of the determined battery status with a battery status which has been determined at an earlier point in time. This interpolation can be carried out, for example, by forming mean values. A weighted interpolation means that the determined battery status or the battery status which has been determined at an earlier point in time is included repeatedly in the formation of the mean value. In this way, the battery status which was determined at an earlier point in time could be weighted, for example, doubly with respect to the determined battery status. In this context, weightings which are not integrals are also possible. The resulting battery status is described by the mean value which is determined in this way. By means of such weighted interpolation it is additionally possible to reduce possibly occurring measurement errors (insofar as they are not systematic). A weighted update therefore takes place. Furthermore, filtering of the measured capacity, of the measured energy content and/or of the determined battery status is possible, in which values are filtered which are considered to be incorrect (for example since they lie outside a typical value range).

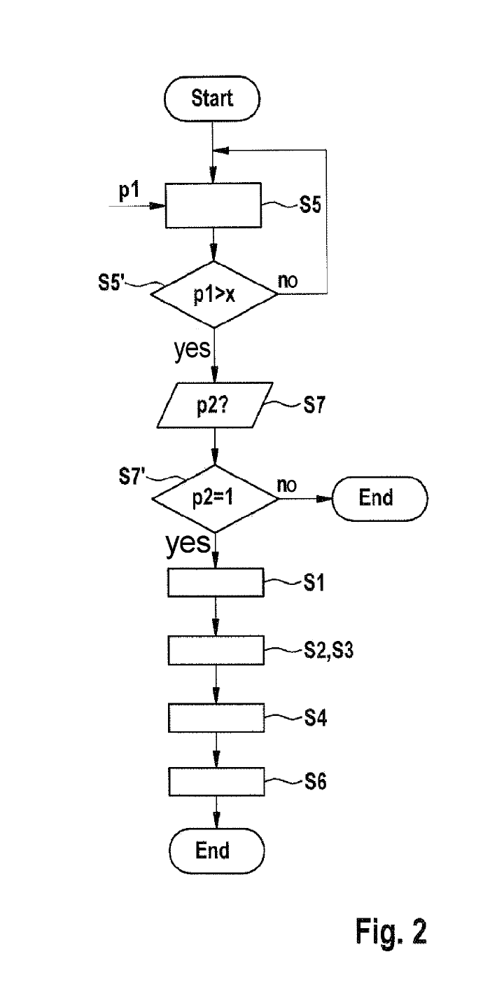

FIG. 2 shows a flowchart of the method according to the invention in a second embodiment. The method is executed by a device for determining a battery status of a vehicle battery in a vehicle. This corresponds in this second embodiment to a battery management system. In order to determine a battery status of a vehicle battery, the first to fourth method steps which are described in the first embodiment are applied.

This means that the vehicle battery is completely discharged, the vehicle battery is completely charged, a capacity and/or an energy content of the vehicle battery are/is measured during the charging of the vehicle battery, and the battery status is determined by means of the capacity and/or the energy content of the vehicle battery. The method is triggered by actuation of the vehicle by a user.

However, in this second embodiment a first decision parameter p1 is interrogated in an introductory method step S5. The first decision parameter p1 can be made available here by other systems which are located in the vehicle or by the battery management system itself. Examples of the first decision parameter p1 are a current date, a mileage or kilometerage of the vehicle, a charge throughput rate of the vehicle battery or an energy throughput rate of the vehicle battery. The interrogated first decision parameter p1 is compared with a predefined threshold value x. This threshold value x can be predefined in the battery management system in the course of a manufacturer or user configuration. If the related decision parameter p1 is higher than the threshold value x, the method is carried on. If the related decision parameter p1 is lower than the threshold value x, the method branches back to the initiating method step S5, by which means the latter is executed again.

In the second embodiment described here, the first decision parameter p1 will be assumed to be the mileage or kilometerage of the vehicle. The threshold value x is predefined by the manufacturer of the battery management system with a value of 5000 km. At the start of the method, the mileage or kilometerage of the vehicle is therefore interrogated from an odometer of the vehicle. The decision parameter p1 which is related in this way is compared in a subsequent comparative method step S5′ with the threshold value x=5000 km. If the related decision parameter p1 is higher than the threshold value x, i.e. p1>x(=5000 km), the method is carried on. If the related decision parameter p1 is lower than the threshold value x, i.e. p1<x(=5000 km), the method branches back to the initiating method step S5, by which means the latter is executed again. In this example, the battery status is therefore determined after kilometerage of the vehicle at 5000 km.

It is also possible to predefine a plurality of threshold values and therefore define intervals. In the embodiment shown in FIG. 2, for this purpose in a concluding method step S6, which is executed after the determination of the battery status in the fourth method step S4, the threshold value x is newly defined. For this purpose, for example a given value can be added to the previous threshold value.

The battery status can be determined, for example, after a certain time (for example every 3 months), after a certain mileage or kilometerage (for example every 5000 km), after a certain charge throughput rate (for example every 2 MAh) or after a certain energy throughput rate (for example every 1 MWh). The vehicle therefore assumes a capacity and energy measurement mode at regular intervals.

Since the discharging and charging of the vehicle battery in the first and second method steps S1, S2 can last several hours, a user should have the possibility of postponing the discharging in the first method step S1 and the charging of the vehicle battery in the second method step S2 if the vehicle is not required in the near future. As is described above, the method is carried on if the related decision parameter p1 is higher than the threshold value x. In this case, after the comparative method step S5′, in an interrogating method step S7 a second decision parameter p2 is interrogated. The decision parameter p2 is preferably defined by inputting of a user. It would therefore be possible to generate, for example on a display in the interior of the vehicle, a message which interrogates the user's consent to further execution of the method. The second decision parameter p2 is set as a function of an input by the user. The second decision parameter p2 is therefore set to “1” if the user desires determination of the battery status and the second decision parameter p2 is set to “0” if the user does not desire this at this point in time since the vehicle is, for example, required again in a brief time. The method is ended or carried on as a function of the second decision parameter p2. Since complete execution of the method, in particular the discharging and charging of the vehicle battery in the first and second method steps S1, S2 requires a considerable period of time for the user, the user is therefore provided with the possibility of aborting the method. This ensures that the vehicle is in an operationally ready state if this is desired by the user.

In a testing method step S7′ it is checked whether the interrogated second decision parameter p2 is equal to “1”. If this is not the case (if the second decision parameter p2 has been set to “0”), the method is ended. The determination of the battery status may not be reached in this case until after renewed triggering of the method. If the interrogated second decision parameter p2 is equal to “1” the method is carried on.

If the second decision parameter p2 is set to “1”, that is to say if determination of the battery status is desired by the user, the first method step, that is to say the discharging of the vehicle battery, is carried out immediately. In the further course of the method, the method is carried out in this case with all the steps according to the first embodiment. Before the termination of the method, the previously described concluding method step S6 is carried out.

In a further alternative embodiment with which the embodiments which have already been described can be combined, the discharging of the vehicle battery is carried out in the first method step S1 during a use of the vehicle in the driving mode. That is to say the vehicle battery is discharged during a journey by the user with the vehicle. The power which is made available by the vehicle battery drops to near to zero, in particular toward the end of the discharging of the vehicle battery. Therefore, electric propulsion which is fed by the battery is no longer ensured. So that propulsion is ensured and the vehicle therefore does not remain in the driving mode, an energy requirement which is not covered by the vehicle battery is covered by an internal combustion engine and therefore compensated thereby. In this context, the energy requirement can either be covered by the fact that the propulsion is performed mechanically by the internal combustion engine or else an electric supply voltage is made available by a generator which is coupled to the internal combustion engine. In this context, the generator can also be the electric motor of the vehicle. The driving power is therefore provided continuously by the internal combustion engine. After the discharging, the vehicle travels in the purely internal combustion engine mode. It is advantageous here if in this state a braking operation is not performed by the electric drive but instead completely by means of conventional braking If the first method step S1 is carried out during the driving mode and the vehicle battery is therefore discharged, it does not have to be possible for this to be perceived specifically by the user, that is to say the driver. Alternatively, the execution of the determination of the battery status can be displayed on a display in the interior of the vehicle.

In a further alternative embodiment, which can also be combined with the embodiments already described, the charging of the vehicle battery is carried out in the second method step S2 during use of the vehicle in the driving mode. Since it is not possible for the vehicle battery to be charged by an external voltage source in the driving mode, the charging of the vehicle battery is carried out by means of an electric motor of the vehicle which is in a generator mode. Such an embodiment is therefore suitable, in particular, for hybrid-electric vehicles (HEV). If the second method step S2 is carried out during the driving mode and the vehicle battery is therefore charged, it does not have to be possible for this to be perceived specifically by the user, that is to say the driver. Alternatively, the execution of the determination of the battery status can be displayed on a display in the interior of the vehicle.

In all the embodiments in which use of the vehicle during the determination of the battery status is not possible, it is advantageous to inform the user of the vehicle about this (for example by means of an indication on a display).

In all the embodiments, a specific battery status can replace a battery status which was determined earlier. The same applies to a resulting battery status, which can replace either a battery status which was determined earlier or a resulting battery status which was determined earlier.

In addition to the written disclosure above, reference is made explicitly to the disclosure in FIGS. 1 and 2.

1. A method for determining a battery status of a vehicle battery in a vehicle, comprising:
complete discharging (S1) of the vehicle battery by vehicle-internal loads of the vehicle,
complete charging (S2) of the vehicle battery,
measuring (S3) a battery parameter of the vehicle battery during the charging (S2) of the vehicle battery, and
determining (S4) the battery status using the battery parameter.

2. The method according to claim 1, characterized in that in an introductory method step (S5) a first decision parameter (p1) is interrogated, and a decision as to whether the method is carried on is carried out on the basis of a comparison of the first decision parameter (p1) with a given threshold value (x), wherein the first decision parameter (p1) is a parameter which describes a period of time, a mileage or kilometerage of the vehicle, a charge throughput rate of the vehicle battery and/or an energy throughput rate of the vehicle battery.

3. The method according to claim 1, characterized in that the charging (S2) of the vehicle battery is carried out with an average discharging current of the vehicle battery.

4. The method according to claim 1, characterized in that the charging (S2) of the vehicle battery is carried out with an average discharging power of the vehicle battery.

5. The method according to claim 1, characterized in that the discharging (S1) of the vehicle battery is carried out during use of the vehicle in the driving mode, wherein an energy requirement which is not covered by the vehicle battery is covered by an internal combustion engine.

6. The method according to claim 1, characterized in that the charging (S2) of the vehicle battery is carried out during use of the vehicle in the driving mode, wherein a charge current is made available by a generator which is driven using an internal combustion engine.

7. The method according to claim 1, characterized in that before the method step of completely discharging (S1) the vehicle battery an interrogation (S7) of a second decision parameter (p2) takes place, wherein inputting of the second decision parameter (p2) by a user is made possible, and the method is ended or carried on as a function of the second decision parameter (p2).

8. The method according to claim 1, characterized in that the method also comprises a weighting in which a resulting battery status is determined by a weighted interpolation of the determined battery status with a battery status which has been determined at an earlier point in time.

9. The method according to claim 1, characterized in that the discharging (S1) of the vehicle battery comprises a concluding phase in which the battery voltage is regulated to a constant voltage value.

10. The method according to claim 1, characterized in that the charging (S2) of the vehicle battery is carried out by an electric motor of the vehicle operating in a generator mode.

11. The method according to claim 1, wherein the battery parameter is a battery capacity.

12. The method according to claim 1, wherein the battery parameter is an energy content of the battery.

13. A device for determining a battery status of a vehicle battery in a vehicle, comprising:
a discharge unit which is configured to discharge completely a vehicle battery by vehicle-internal loads of the vehicle,
a charging unit which is configured to charge the vehicle battery completely,
a measuring unit which is configured to measure a battery parameter during the charging of the vehicle battery, and
a determining unit which is configured to determine the battery status using the battery parameter.

14. The device according to claim 13, wherein the battery parameter is a battery capacity.

15. The device according to claim 13, wherein the battery parameter is an energy content of the battery.
